(19) United States
(12) Patent Application Publication
(10) Pub. No.: US 2025/0292808 A1
(43) Pub. Date: Sep. 18, 2025

(54) MEMORY DEVICE

(71) Applicant: Kioxia Corporation, Tokyo (JP)

(72) Inventor: Yosuke KOBAYASHI, Seoul (KR)

(73) Assignee: Kioxia Corporation, Tokyo (JP)

(21) Appl. No.: 19/071,957

(22) Filed: Mar. 6, 2025

(30) Foreign Application Priority Data
Mar. 18, 2024 (JP) 2024-042386

(51) Int. Cl. G11C 5/06; G11C 13/00; H10B 63/00

(52) U.S. Cl. CPC G11C 5/063; G11C 13/0023; H10B 63/20; H10B 63/84

(57) ABSTRACT

According to one embodiment, a memory device includes a plurality of first wiring lines each extending in a first direction, a plurality of second wiring lines each extending in a second direction, a plurality of memory cells provided between the first and second wiring lines, each including a variable resistance memory element and a switching element connected to each other in series, and an address assignment circuit assigning addresses to the first wiring lines, respectively. When the first wiring lines include a first short-circuited wiring line and a second short-circuited wiring line that are short-circuited to each other, the address assignment circuit assigns a common address to the first and second short-circuited wiring lines.

### CROSS-REFERENCE TO RELATED APPLICATIONS

This application is based upon and claims the benefit of priority from Japanese Patent Application No. 2024-042386, filed Mar. 18, 2024, the entire contents of which are incorporated herein by reference.

### FIELD

Embodiments described herein relate generally to a memory device.

### BACKGROUND

A memory device has been proposed in which a plurality of variable resistance memory elements (resistance change memory elements) such as magnetoresistance effect elements are integrated on a semiconductor substrate.

### BRIEF DESCRIPTION OF THE DRAWINGS

FIG. 1 is a block diagram showing a configuration of a memory device according to an embodiment.

FIG. 2 is a perspective view schematically showing a configuration of a memory cell array portion included in the memory device according to the embodiment.

FIG. 3 is a cross-sectional view schematically showing a basic configuration of a magnetoresistance effect element included in the memory cell array portion of the memory device according to the embodiment.

FIG. 4 is a cross-sectional view schematically showing a basic configuration of a selector included in the memory cell array portion of the memory device according to the embodiment.

FIG. 5 is a diagram schematically showing configurations of the memory cell array portion, a drive circuit, and an address assignment circuit included in the memory device according to the embodiment.

FIG. 6 is a diagram schematically showing an example of a configuration of a connection relationship setting circuit and the like, included in the address assignment circuit of the memory device according to the embodiment.

FIG. 7 is a diagram schematically showing another example of the configuration of the connection relationship setting circuit and the like, included in the address assignment circuit of the memory device according to the embodiment.

FIG. 8 is a diagram schematically showing still another example of the configuration of the connection relationship setting circuit and the like, included in the address assignment circuit of the memory device according to the embodiment.

FIG. 9 is a diagram schematically showing still another example of the configuration of the connection relationship setting circuit and the like, included in the address assignment circuit of the memory device according to the embodiment.

FIG. 10 is a flowchart showing an operation of the memory device according to the embodiment.

FIG. 11 is a diagram showing a detection processing for short-circuiting errors in the memory device according to the embodiment.

FIG. 12 is a block diagram showing a configuration of a modified example of the memory device according to the embodiment.

### DETAILED DESCRIPTION

In general, according to one embodiment, a memory device includes: a plurality of first wiring lines each extending in a first direction; a plurality of second wiring lines each extending in a second direction intersecting the first direction; a plurality of memory cells provided between the plurality of first wiring lines and the plurality of second wiring lines, each including a variable resistance memory element and a switching element connected to each other in series; and an address assignment circuit assigning addresses to the plurality of first wiring lines, respectively, wherein when the plurality of first wiring lines include a first short-circuited wiring line and a second short-circuited wiring line that are short-circuited to each other, the address assignment circuit assigns a common address to the first short-circuited wiring line and the second short-circuited wiring line.

Embodiments will be described hereinafter with reference to the accompanying drawings.

FIG. 1 is a block diagram showing a configuration of a memory device according to an embodiment.

The memory device shown in FIG. 1 comprises a memory cell array portion 100, a drive circuit 200, an address assignment circuit 300, a detection processing circuit 400, and a redundancy control circuit 500.

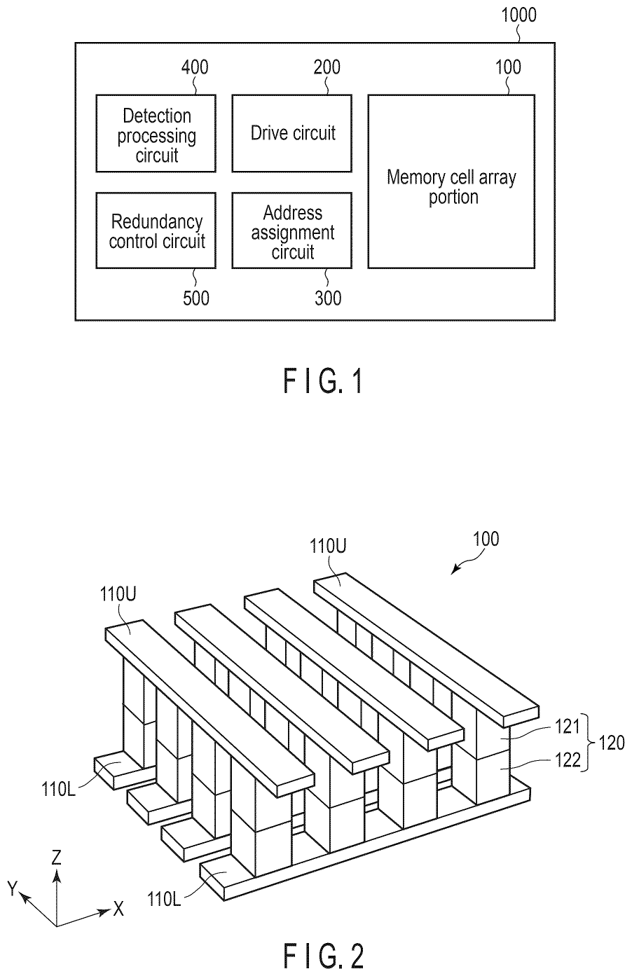

FIG. 2 is a perspective view schematically showing a configuration of the memory cell array portion 100.

As shown in FIG. 2, the memory cell array portion 100 includes a plurality of lower wiring lines 110L each extending in an X direction, a plurality of upper wiring lines 110U each extending in a Y direction, and a plurality of memory cells 120 provided between the plurality of lower wiring lines 110L and the plurality of upper wiring lines 110U. Either the lower wiring lines 110L or upper wiring lines 110U correspond to word lines, and the others of the lower wiring lines 110L and upper wiring lines 110U correspond to bit lines.

Each of the plurality of memory cells 120 includes a magnetoresistance effect element (variable resistance memory element (resistance change memory element)) 121 and a selector (switching element) 122 connected in series. The magnetoresistance effect element 121 and the selector 122 are stacked in the Z direction. Note that in the example shown in FIG. 2, the magnetoresistance effect element 121 is provided on an upper layer side of the selector 122, but the magnetoresistance effect element 121 may as well be provided on a lower layer side of the selector 122.

Here, the X direction, the Y direction, and the Z direction are directions intersecting each other. More specifically, the X direction, Y direction, and Z direction are orthogonal to each other.

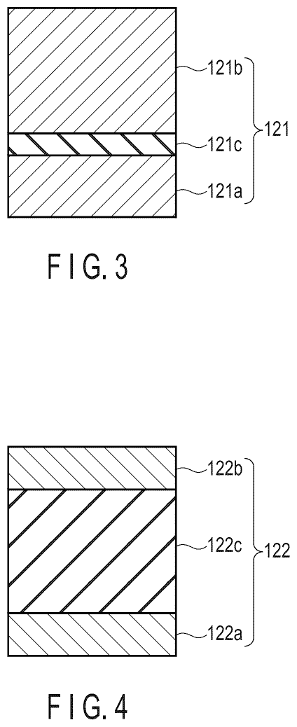

FIG. 3 is a cross-sectional view schematically showing a basic configuration of the magnetoresistance effect element 121.

As shown in FIG. 3, the magnetoresistance effect element 121 includes a storage layer (first magnetic layer) 121a, a reference layer (second magnetic layer) 121b, and a tunnel barrier layer (nonmagnetic layer) 121c, and has a configuration in which the storage layer 121a, the reference layer 121b, and the tunnel barrier layer 121c are stacked in the Z direction.

The storage layer 121a is a ferromagnetic layer having a variable magnetization direction. The reference layer 121b is a ferromagnetic layer having a fixed magnetization direction. The tunnel barrier layer 121c is an insulating layer provided between the storage layer 121a and the reference layer 121b. Note that the variable magnetization direction means that the magnetization direction changes in response to a predetermined writing current. The fixed magnetization direction means that the magnetization direction does not change in response to a predetermined writing current.

When the magnetization direction of the storage layer 121a is parallel to the magnetization direction of the reference layer 121b, the magnetoresistance effect element 121 exhibits a low-resistance state which has a relatively low resistance, whereas when the magnetization direction of the storage layer 121a is antiparallel to the magnetization direction of the reference layer 121b, the magnetoresistance effect element 121 exhibits a high-resistance state which has a relatively high resistance. With this configuration, the magnetoresistance effect element 121 can store binary data according to its resistance state.

Note that the magnetoresistance effect element 121 shown in FIG. 3 is a bottom-free type magnetoresistance effect element in which the storage layer 121a is located on a lower layer side of the reference layer 121b, but a top-free type magnetoresistance effect element in which the storage layer 121a is located on an upper side of the reference layer 121b may as well be used.

FIG. 4 is a cross-sectional view schematically showing a basic structure of the selector 122.

The selector 122 is a two-terminal switching element that includes a bottom electrode 122a, a top electrode 122b, and a selector material layer 122c, and has the characteristic of changing from an off state to an on state when the voltage applied between the two terminals (between the bottom electrode 122a and the top electrode 122b) reaches or exceeds a threshold voltage.

When a voltage is applied between a selected lower wiring line 110L and a selected upper wiring line 110U, and a voltage higher than or equal to the threshold voltage is applied to the selected selector 122 included in the selected memory cell 120, a current flows to the selected magnetoresistance effect element 121 connected in series with the selected selector 122, thus making it possible to carry out read or write with respect to the selected magnetoresistance effect element 121.

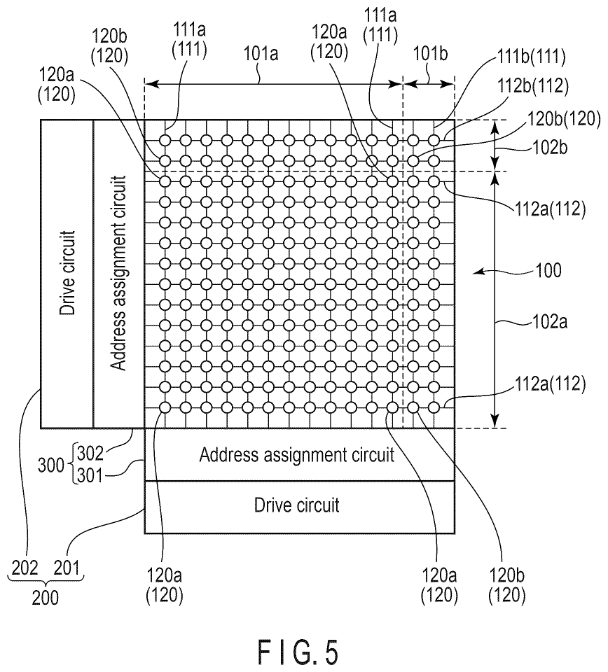

FIG. 5 is a diagram schematically showing a configuration of each of the memory cell array portion 100, the drive circuit 200, and the address assignment circuit 300.

As shown in FIG. 5, the memory cell array portion 100 includes a plurality of first wiring lines 111, a plurality of second wiring lines 112, and a plurality of memory cells 120 connected between the first wiring lines 111 and the second wiring lines 112. The first wiring lines 111 correspond to the lower wiring lines 110L or the upper wiring lines 110U shown in FIG. 2, and the second wiring lines 112 correspond to the other ones of the lower wiring lines 110L and the upper wiring line 110U shown in FIG. 2. The memory cells 120 correspond to the memory cells 120 shown in FIG. 2.

The plurality of first wiring lines 111 include a plurality of normal wiring lines 111a and at least one redundancy line 111b. Similarly, the plurality of second wiring lines 112 include a plurality of normal wiring lines 112a and at least one redundancy line 112b. The plurality of memory cells 120 include a plurality of normal memory cells 120a and a plurality of redundancy memory cells 120b.

The plurality of normal wiring lines 111a are regular first wiring lines 111. The at least one redundancy line 111b is the first wiring line 111 other than the normal wiring lines 111a, and is a preliminary first wiring lines 111 to be used when the normal wiring lines 111a include a faulty wiring line, as in the case of the normal redundancy lines. In this embodiment, the at least one redundancy line 111b is used when the normal wiring lines 111a include short-circuited wiring line that are short-circuited to each other.

As to the normal wiring lines 112a and the at least one redundancy line 112b, the above-provided explanation for the case of the normal wiring lines 111a and the at least one redundancy line 111b can be applied.

The at least one redundancy line 111b is entirely located in an area 101b outside an area 101a where the normal wiring lines 111a are provided, and the at least one redundancy line 112b is entirely located in an area 102b outside an area 102a where the normal wiring lines 112a are provided.

The drive circuit 200 includes a drive circuit 201 and another drive circuit 202. The drive circuit 201 generates drive signals to be supplied to the plurality of memory cells 120 via the plurality of first wiring lines 111, and the drive circuit 202 generates drive signals to be supplied to the plurality of memory cells 120 via the plurality of second wiring lines 112.

When a selection signal is supplied to a selected first wiring line 111 from the drive circuit 201 and a selection signal is supplied to a selected second wiring line 112 from the drive circuit 202, the selected memory cell 120 connected between the selected first wiring lines 111 and the selected second wiring lines 112 is set in the on state, by which it becomes possible to carry out read or write with respect to the selected memory cell 120.

The address assignment circuit 300 includes an address assignment circuit 301 and an address assignment circuit 302. The address assignment circuit 301 is provided between the drive circuit 201 and the plurality of first wiring lines 111, and assigns addresses to the plurality of first wiring lines 111, respectively. The address assignment circuit 302 is provided between the drive circuit 202 and the plurality of second wiring lines 112, and assigns addresses to the plurality of second wiring lines 112, respectively.

In this embodiment, the address assignment circuit 301 assigns, when the plurality of first wiring lines 111 include a plurality of short-circuited wiring lines that are short-circuited to each other, a common address to the plurality of short-circuited wiring lines. More specifically, when the plurality of normal wiring lines 111a include a plurality of short-circuited wiring lines that are short-circuited to each other, the address assignment circuit 301 assigns a common address to the plurality of short-circuited wiring lines. A short-circuiting error is an inter-wiring error (bridge fault) that occurs between first wiring lines 111 that are adjacent to each other, and therefore the plurality of short-circuited wiring lines are first wiring lines 111 that are disposed sequentially.

Similarly, the address assignment circuit 302 assigns, when a plurality of short-circuited wiring lines that are short-circuited to each other are included in the plurality of second wiring lines 112, a common address to the plurality of short-circuited wiring lines. More specifically, when a plurality of short-circuited wiring lines that are short-circuited to each other are included in the normal wiring lines 112a, the address assignment circuit 302 assigns a common address to the plurality of short-circuited wiring lines. As to the second wiring lines 112 as well, the plurality of short-circuited wiring lines are second wiring lines 112 that are sequentially disposed.

Configuration examples and functions of the address assignment circuit 300 will now be explained. Note that, for the sake of simplicity of explanation, the address assignment circuit 301 will be focused in the following descriptions, but the address assignment circuit 302 has configurations and functions similar to those of the address assignment circuit 301.

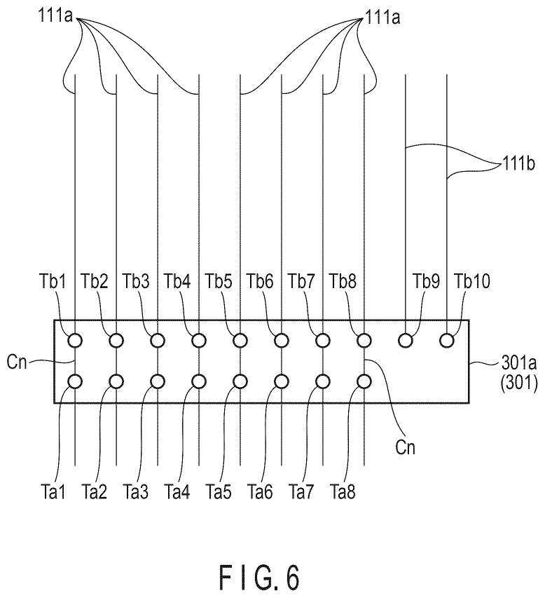

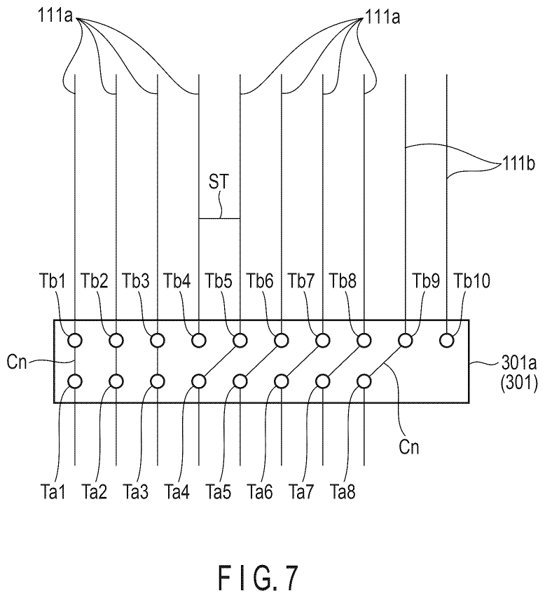

FIGS. 6 and 7 are diagrams schematically showing examples of the configuration of the connection relationship setting circuit 301a and the like, included in the address assignment circuit 301. FIG. 6 shows the case where the plurality of first wiring lines 111 (specifically, the plurality of normal wiring lines 111a) do not include any short-circuited wiring lines that are short-circuited to each other. FIG. 7 shows the case where the plurality of first wiring lines 111 (specifically, the plurality of normal wiring lines 111a) include short-circuited wiring lines that are short-circuited to each other.

As shown in FIGS. 6 and 7, the connection relationship setting circuit 301a includes a plurality of input terminals Ta (Ta1 to Ta8), a plurality of output terminals Tb (Tb1 to Tb10), and a plurality of connection members Cn, and sets the connection relationship between the plurality of input terminals Ta and the plurality of output terminals Tb, respectively.

To the plurality of input terminals Ta, drive signals supplied to the plurality of memory cells 120 via the plurality of first wiring lines 111 are input. The drive signals are supplied to the plurality of input terminals Ta from the drive circuit 201 shown in FIG. 5. The plurality of output terminals Tb output the drive signals input to the plurality of input terminals Ta to the plurality of first wiring lines 111. The connection relationship between the plurality of input terminals Ta and the plurality of output terminals Tb is set as appropriate by the plurality of connection members Cn.

The connection relationship setting circuit 301a includes, for example, a plurality of fuses and the like, and thus it is possible to set the connection relationship between the plurality of input terminals Ta and the plurality of output terminals Tb by adjusting the connection relationship using the plurality of fuses.

As shown in FIG. 6, when the plurality of normal wiring lines 111a do not include any short-circuited wiring lines that are short-circuited to each other, the plurality of input terminals Ta1 to Ta8 are connected to the plurality of output terminals Tb1 to Tb8 via the plurality of connecting members Cn, respectively, and the output terminals Tb9 and Tb10 are not used. In other words, only the normal wiring lines 111a are used, and the redundancy lines 111b are not used.

As shown in FIG. 7, when the plurality of normal wiring lines 111a include short-circuited wiring lines that are short-circuited to each other, a common address is assigned to a plurality of short-circuited wiring lines (two short-circuited wiring lines in the example shown in FIG. 7). In other words, a common address is assigned to two adjacent short-circuited wiring lines (two adjacent normal wiring lines 111a) that are short-circuited by the short portion ST, and a common drive signal is supplied to the two adjacent short-circuited wiring lines.

More specifically, in the example shown in FIG. 7, one of the two short-circuited wiring lines is defined as a first short-circuited wiring line, and the other of the two short-circuited wiring lines is defined as a second short-circuited wiring line. Then, the output terminal Tb5 of the plurality of output terminals Tb1 to Tb8, that is provided for the first short-circuited wiring line, and one input terminal Ta4 of the plurality of input terminals Ta1 to Ta8, are connected to each other, whereas the output terminal Tb4 of the plurality of output terminals Tb1 to Tb8, that is provided for the second short-circuited wiring line and the above-mentioned one input terminal Ta4 are not connected to each other.

The two short-circuited wiring lines (the first and second short-circuited wiring lines) described above are electrically connected to each other by a short-circuited portion ST. With this configuration, a common address is assigned to the two short-circuited wiring lines by the input terminal Ta4, and therefore a common drive signal is supplied to the two short-circuited wiring lines.

In the example shown in FIG. 7, the input terminal Ta8 is connected to the output terminal Tb9 provided for the redundancy line 111b. With this configuration, the drive signal input to the input terminal Ta8 is supplied to the redundancy line 111b connected to the output terminal Tb9.

As can be seen from the above, in this embodiment, instead of using two redundancy lines 111b in place of two short-circuited wiring lines, a common address is assigned to the two short-circuited wiring lines. Thus, the number of redundancy lines 111b used for redundancy processing is reduced.

Here, the memory cell provided between the first short-circuited wiring line and one of the second wiring lines is referred to as a first memory cell, and the memory cell provided between the second short-circuited wiring line and the one of the second wiring lines is referred to as a second memory cell. As described above, in this embodiment, a common address is assigned to the first and second short-circuited wiring lines. With this configuration, when a common drive signal (selection signal) is supplied to the first and second short-circuited wiring lines, both the first and second memory cells are set in a selectable state. Here, since the first and second memory cells are controlled by a common address, both the first and second memory cells must not be selected, but only one of the first and second memory cells must be selected. In this embodiment, it is possible to select only one of the first and second memory cells, reasons of which will now be described in the following.

The selection voltage (threshold voltage) of memory cell varies from one memory cell to another. Therefore, only the memory cell having a lower threshold voltage out of the first and second memory cells is selected as a usable memory cell. More specifically, during the forming process performed at the time of initialization, only one of the first and second memory cells is selected and subjected to the forming process. Here, when carrying out write or read, only the memory cell that has been subjected to the forming process functions as a usable memory cell.

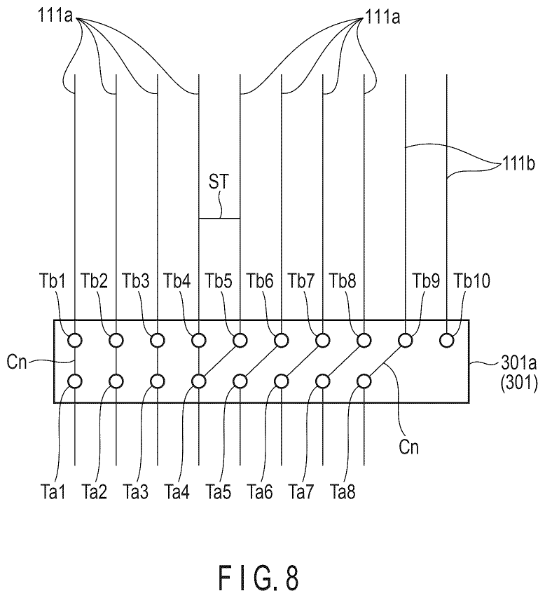

FIG. 8 is a diagram schematically showing another example of the connection relationship setting circuit 301a and the like, included in the address assignment circuit 301.

In the example shown in FIG. 8, the output terminal Tb5 provided for the first short-circuited wiring line, out of the plurality of output terminals Tb1 to Tb8 and one input terminal Ta4 of the plurality of input terminals Ta1 to Ta8 are connected to each other, and the output terminal Tb4 provided for the second short-circuited wiring line, out of the plurality of output terminals Tb1 to Tb8 is also connected to the above-mentioned one input terminal Ta4. The other basic configuration is similar to that shown in FIG. 7.

In this example as well, as in the case of the example shown in FIG. 7, a common address is assigned to two adjacent short-circuited wiring lines (the first and second short-circuited wiring lines) by the input terminal Ta4, and a common drive signal is supplied to the two adjacent short-circuited wiring lines.

Further, in this example, both the output terminal Tb5 provided for the first short-circuited wiring line and the output terminal Tb4 provided for the second short-circuited wiring line are connected to one input terminal Ta4. With this configuration, it is possible to supply a common drive signal to the two short-circuited wiring lines (the first and second short-circuited wiring lines) more reliably.

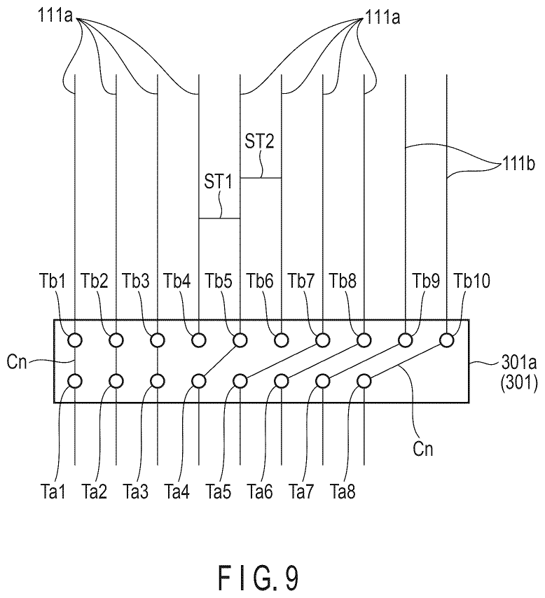

FIG. 9 is a diagram schematically showing still another example of the connection relationship setting circuit 301a and the like, included in the address assignment circuit 301.

In the example shown in FIG. 9, three first wiring lines 111 arranged sequentially are short-circuited to each other. That is, the plurality of first wiring lines 111 further include a third short-circuited wiring line that is short-circuited to the first and second short-circuited wiring lines. More specifically, the first short-circuited wiring line and the second short-circuited wiring line, which are adjacent to each other, are short-circuited by the short-circuited portion ST1, and the first short-circuited wiring line and the third short-circuited wiring line, which are adjacent to each other, are short-circuited by the short-circuited portion ST2.

In this example, a common address is assigned to the three sequentially disposed short-circuited wiring lines (the first, second and third short-circuited wiring lines) by the input terminal Ta4, and a common drive signal is supplied to the three sequentially disposed short-circuited wiring lines.

Further, in this example, the input terminal Ta7 is connected to the output terminal Tb9, and the input terminal Ta8 is connected to the output terminal Tb10. With this configuration, the drive signal input to the input terminal Ta7 is supplied to the redundancy line 111b connected to the output terminal Tb9, and the drive signal input to the input terminal Ta8 is supplied to the redundancy line 111b connected to the output terminal Tb10.

Note that in the example shown in FIG. 9, the output terminal Tb5 provided for the first short-circuited wiring line and the input terminal Ta4 are connected to each other, and the output terminal Tb4 provided for the second short-circuited wiring line and the output terminal Tb6 provided for the third short-circuited wiring line are not connected to the input terminal Ta4, but it is also possible to connect two or more of the output terminals Tb4, Tb5, and Tb6 to the input terminal Ta4.

Returning to the explanation of FIG. 1, in the memory device shown in FIG. 1, the detection processing circuit 400 and the redundancy control circuit 500 are built in the same integrated circuit chip 1000, which includes the memory cell array portion 100, the drive circuit 200, and the address assignment circuit 300.

The detection processing circuit 400 performs detection processing for short-circuiting errors in the plurality of first wiring lines 111 (specifically, the plurality of normal wiring lines 111a) and detection processing for short-circuiting errors in the plurality of second wiring lines 112 (specifically, the plurality of normal wiring lines 112a).

More specifically, the detection processing circuit 400 detects whether or not the plurality of first wiring lines 111 include short-circuited wiring lines that are short-circuited to each other. When short-circuited wiring lines are included, which ones of the plurality of first wiring lines 111 are short-circuited are detected (that is, the locations of the short-circuited wiring lines are detected). This description is applied to the plurality of second wiring lines 112 as well.

The detection processing operation described above, which is performed by the detection processing circuit 400, can be performed after the integrated circuit chip 1000 is packaged.

The redundancy control circuit 500 performs redundancy control. More specifically, the redundancy control circuit 500 controls the operation of setting the connection relationship, which is performed by the connection relationship setting circuit 301a included in the address assignment circuit 301, based on the results of the detection by the detection processing circuit 400. In other words, the redundancy control circuit 500 controls the operation of setting the connection relationship between the plurality of input terminals Ta and the plurality of output terminals Tb in the connection relationship setting circuit 301a. Note that the address assignment circuit 302 is similarly controlled by the redundancy control circuit 500.

The above-described redundancy control operation to be carried out by the redundancy control circuit 500 can be performed after the integrated circuit chip 1000 is packaged.

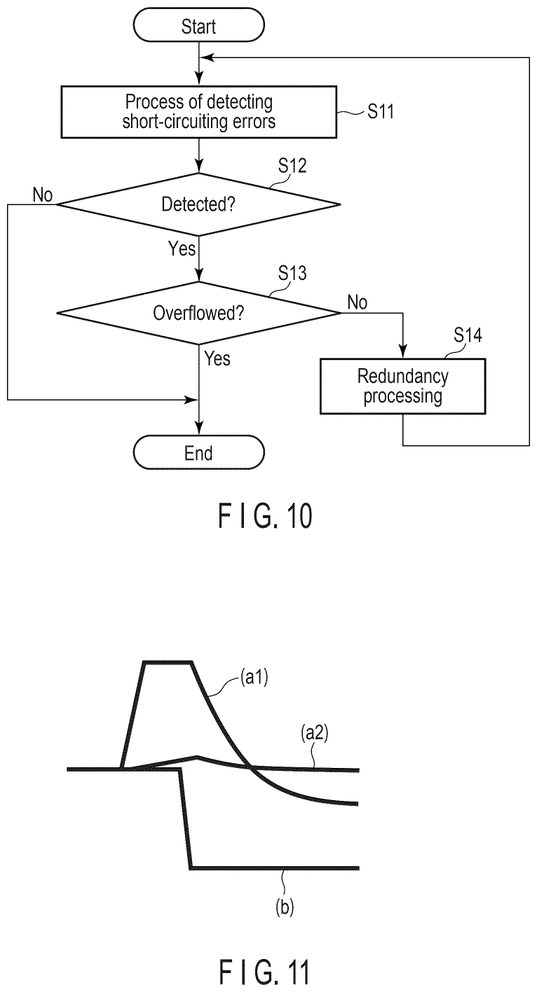

Next, the operation of this embodiment will be explained with reference to the flowchart shown in FIG. 10. Specifically, the operation of initialization of the memory device described above will be explained. For the sake of simplicity of explanation, the following descriptions focus on the first wiring lines 111 as an example, but note that a similar operation is performed for the second wiring lines 112.

First, after packaging the integrated circuit chip 1000, the process of detecting short-circuiting errors is performed by the detection processing circuit 400 (S11). In other words, a self-test for short-circuiting errors is performed within the integrated circuit chip 1000.

FIG. 11 shows the detection processing for short-circuiting errors. More specifically, this diagram shows potentials (a1 and a2) of selected first wiring lines 111 and a potential (b) of a selected second wiring lines 112 when current is allowed to flow between the selected first wiring lines 111 and the selected second wiring line 112.

In the case where there is no short-circuit error, a normal current flows between the selected first wiring line 111 and the selected second wiring line 112 via the selected memory cell, and therefore the potential rise of the selected first wiring line 111 is assured, and characteristics shown by (a1) is obtained. By contrast, if there is a short-circuit error, current flows between adjacent short-circuit wiring lines (that is, between the selected first wiring line 111 and an unselected first wiring line 111 located adjacent to the selected first wiring line 111), and therefore the potential rise of the selected first wiring line 111 is not obtained, and characteristics such as shown by (a2) is exhibited. In this manner, it is possible to detect a short-circuiting error by detecting the potential of the selected first wiring line 111.

Next, it is determined whether or not a short-circuiting error has been detected (S12).

When a short-circuiting error has not been detected, the connection relationship setting circuit 301a is in the state shown in FIG. 6, and the operation of initialization is terminated without performing the redundancy processing.

When a short-circuiting error has been detected, it is determined whether the number of redundancy lines 111b overflows (S13). That is, if there are an excessive number of short-circuited wiring lines, the number of redundancy lines 111b is insufficient. In such a case, it is determined that an overflow state is occurring, and the initialization operation is terminated without performing the redundancy processing.

In the case where the number of redundancy lines 111b does not overflow, the redundancy processing described above is performed (S14), and the process returns to step S11, in which the detection processing for short-circuiting errors is performed again.

As described above, in this embodiment, instead of replacing all short-circuited wiring lines with redundancy lines as in the conventional techniques, a common address is assigned and used for a plurality of short-circuited wiring lines that are short-circuited to each other, and therefore the number of redundancy lines used for redundancy processing can be reduced.

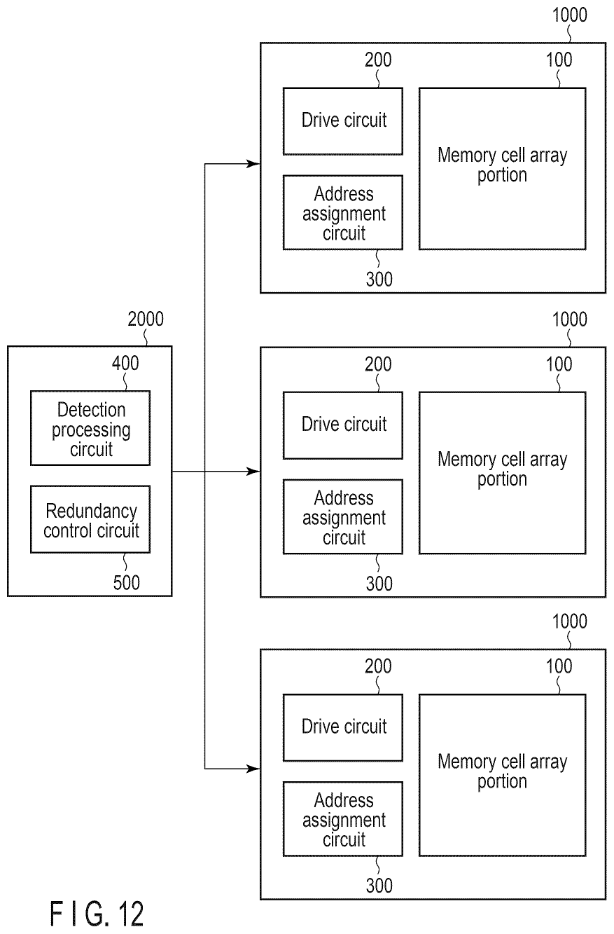

FIG. 12 is a block diagram showing a configuration of a modified example of the memory device of this embodiment.

In the above-mentioned embodiment, the detection processing circuit 400 and the redundancy control circuit 500 are built in the integrated circuit chip 1000, which includes the memory cell array portion 100, the drive circuit 200, and the address assignment circuit 300, whereas in the modified example, the detection processing circuit 400 and the redundancy control circuit 500 are not built in the integrated circuit chip 1000, but are provided in an external controller 2000.

In this modified example as well, the basic configurations of the memory cell array portion 100, the drive circuit 200, and the address assignment circuit 300 are similar to those of the embodiment provided above. Further, the operations performed by the detection processing circuit 400 and the redundancy control circuit 500 are similar to those of the embodiment provided above. Thus, it is possible according to this modified example as well to obtain advantageous effects similar to those of the above-provided embodiment.

Note that the above-provided embodiment and modified example present examples in which the detection for short-circuiting errors and the redundancy processing are performed after the integrated circuit chip 1000 is packaged, but these processes may as well be performed before packaging. More specifically, the above-mentioned processes may be performed before a state where a plurality of integrated circuit chips 1000 are separated from the semiconductor wafer, and thereafter the plurality of integrated circuit chips 1000 may be separated from the semiconductor wafer so as to be packaged.

Further, in the above-described embodiment, the address assignment circuit 301 adopts a structure that includes the connection relationship setting circuit 301a shown in FIGS. 6 to 9, but some other structure may as well be adopted as long as it can assign a common address to a plurality of short-circuited wiring lines that are short-circuited to each other are included in the plurality of first wiring lines 111. This is also the case for the address assignment circuit 302.

Furthermore, the above-described embodiment uses magnetoresistance effect elements as variable resistance memory elements, but other variable resistance memory elements may as well be used.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory device comprising:
a plurality of first wiring lines each extending in a first direction;
a plurality of second wiring lines each extending in a second direction intersecting the first direction;
a plurality of memory cells provided between the plurality of first wiring lines and the plurality of second wiring lines, each including a variable resistance memory element and a switching element connected to each other in series; and
an address assignment circuit assigning addresses to the plurality of first wiring lines, respectively,
wherein
when the plurality of first wiring lines include a first short-circuited wiring line and a second short-circuited wiring line that are short-circuited to each other, the address assignment circuit assigns a common address to the first short-circuited wiring line and the second short-circuited wiring line.

2. The memory device of claim 1, further comprising:
a plurality of input terminals to which drive signals to be supplied to the plurality of memory cells via the plurality of first wiring lines are input; and
a plurality of output terminals which output the drive signals input to the plurality of input terminals to the plurality of first wiring lines,
wherein
the address assignment circuit includes a connection relationship setting circuit which sets a connection relationship between the plurality of input terminals and the plurality of output terminals.

3. The memory device of claim 2, wherein
the connection relationship setting circuit connects a first output terminal of the plurality of output terminals, which is provided for the first short-circuited wiring line, to one of the plurality of input terminals, and does not connect a second output terminal of the plurality of output terminals, which is provided for the second short-circuited wiring line, to the one of the plurality of input terminals.

4. The memory device of claim 2, wherein
the connection relationship setting circuit connects a first output terminal of the plurality of output terminals, which is provided for the first short-circuited wiring line, to one of the plurality of input terminals, and connects a second output terminal of the plurality of output terminals, which is provided for the second short-circuited wiring line, to the one of the plurality of input terminals.

5. The memory device of claim 1, wherein
when the plurality of first wiring lines further include a third short-circuited wiring line that is short-circuited to the first and second short-circuited wiring lines, the address assignment circuit assigns a common address to the first, second, and third short-circuited wiring lines.

6. The memory device of claim 1, wherein
when a memory cell of the plurality of memory cells, which is provided between the first short-circuited wiring line and one of the plurality of second wiring lines is defined as a first memory cell, and a memory cell of the plurality of memory cells, which is provided between the second short-circuited wiring line and the one of the plurality of second wiring lines is defined as a second memory cell, one of the first memory cell and the second memory cell functions as a usable cell.

7. The memory device of claim 1, wherein
the plurality of first wiring lines include a plurality of normal wiring lines and at least one redundancy line used when the plurality of normal wiring lines include short-circuited wiring lines that are short-circuited to each other.

8. The memory device of claim 7, wherein
the at least one redundancy line is provided in an area outside an area where the plurality of normal wiring lines are provided.

9. The memory device of claim 1, further comprising:
a detection processing circuit which performs detection processing for a short-circuiting error in the plurality of first wiring lines, and which is built in a chip that includes the plurality of first wiring lines, the plurality of second wiring lines, the plurality of memory cells, and the address assignment circuit.

10. The memory device of claim 9, wherein
the detection processing performed by the detection processing circuit can be performed after the chip is packaged.

11. The memory device of claim 1, further comprising:
a redundancy control circuit which performs redundancy control, and which is built in a chip that includes the plurality of first wiring lines, the plurality of second wiring lines, the plurality of memory cells, and the address assignment circuit.

12. The memory device of claim 11, wherein
the redundancy control performed by the redundancy control circuit can be performed after the chip is packaged.

13. The memory device of claim 1, wherein
the variable resistance memory element and the switching element are stacked in a third direction intersecting the first and second directions.

14. The memory device of claim 1, wherein
the variable resistance memory element is a magnetoresistance effect element.

15. The memory device of claim 1, wherein
the switching element is a two-terminal switching element, and having a characteristic of changing from an off state to an on state when a voltage applied between two terminals thereof reaches or exceeds a threshold voltage.
